(19) United States
(12) Patent Application Publication
(10) Pub. No.: US 2005/0007154 A1
(43) Pub. Date: Jan. 13, 2005

(54) System and method for evaluating the speed of a circuit

(76) Inventors: Benjamin J. Patella, Fort Collins, CO (US); Eric S. Fetzer, Longmont, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/614,309

(22) Filed: Jul. 7, 2003

(51) Int. Cl. H03D 3/00

(52) U.S. Cl. 327/2

(57) ABSTRACT

A method and system for evaluating the speed of a circuit are provided. In accordance with one embodiment, the method comprises determining during a first operational phase of a first operational cycle the propagation speed of a first signal in a first signal propagation path, and concurrently preventing all signals from propagating in a second signal propagation path substantially parallel with the first signal propagation path. The method further comprises determining during a second operational phase alternating with the first operational phase the propagation speed of a second signal in the second signal propagation path, and concurrently preventing all signals from propagating in the first signal propagation path.

### CROSS-REFERENCE TO RELATED APPLICATIONS

This application is related to co-pending and commonly assigned U.S. patent application Ser. No. 09/811,256, (Publication No. 2002/0130695, published on Sep. 19, 2002), entitled “SYSTEM AND METHOD FOR DYNAMICALLY CONTROLLING AN INTEGRATED CIRCUIT'S CLOCK,” filed Mar. 16, 2001; the disclosure of which is hereby incorporated herein by reference.

### BACKGROUND

The speed of digital circuitry depends on operating supply voltage, operating temperature, and processing effects that occur during fabrication. For example, digital circuits run faster with increasing supply voltage and run slower with decreasing supply voltage. In systems where it is required to measure the speed of digital circuits, a delay line may be used, because it can be placed on the same microchip substrate as the digital system circuitry. Therefore, its speed is affected by the same process, voltage, and temperature as the rest of the digital system.

Using delay lines to measure the speed of digital circuitry is an important component in a variable voltage and variable frequency power management system. The dynamic or switching component of power dissipation in digital circuits is P=C*f*VDD\hat{ }2. Where P is the dynamic power dissipation, C is the parasitic load of the circuit nodes that switch logic values, f is the chip operating frequency and VDD is the supply voltage. Note that this equation shows that power dissipation is proportional to the supply voltage squared. In a dynamic power management system, a power management controller measures the power dissipation of the digital circuitry. If it detects that the system is exceeding some power budget, the controller will decrease the system supply voltage VDD to achieve significant power savings (since VDD is a squared term in the dynamic power equation). However, since this decrease in supply voltage will cause the system's circuits to run slower, the chip operating frequency must also be decreased, so that the system does not miss its timing deadlines. Specifically, there are some critical paths in the digital system that barely meet their timing deadlines at the chip's nominal operating supply voltage and frequency. For example, a timing deadline is an arrival time for a logical result to be latched into a clocking element, such as a DQ flip flop. When the power management controller decreases the supply voltage, this critical path will slow down, such that the critical path result is not computed fast enough to be latched into the DQ flip flop. This can corrupt the computations of the entire digital system. By decreasing the operating frequency of the system, i.e. slowing down the system clock, the deadlines for critical path results are moved later in time. Even though the critical path is slower, the correct result is still latched.

FIG. 1A represents system 10 containing a traditional delay line 13 including a chain of inverters 14-1, . . . , 14-4. Test pulse generator 12 with start terminal 101 is connected through input line 102 to the inverting input terminal of first inverter 14-1. The output terminal of first inverter 14-1 is connected through output line 103 to the inverting input terminal of second inverter 14-2. The output terminal of second inverter 14-2 is in turn connected through output line 104 to the inverting input terminal of third inverter 14-3. The output terminal of third inverter 14-3 is finally connected through output line 105 to the inverting input terminal of final inverter 14-4. Inverters 14-1, . . . , 14-4 are typically all interconnected with a common microchip VDD voltage supply bus 110. The output terminal of final inverter 14-4 is coupled to speed comparison logic module 15 through output line 106. Speed comparison logic module 15 is coupled with an additional input line, evaluate line 107, and two output logic lines, namely slow output logic line 108 and fast output logic line 109.

FIG. 1B is a timing diagram depicting signals occurring in traditional operation of delay line 13. Delay line 13 is used to measure circuit (signal propagation) speed by applying a START signal to start terminal 101, causing test pulse generator 12 to drive IN pulse 112 through input line 102 onto delay line 13 through the inverting input terminal of first inverter 14-1. IN pulse 112 propagates through delay line 13, as depicted by signals 113, 114, and 115 at respective output lines 103, 104, and 105, to provide output pulse 116 on output line 106. The arrival time at speed comparison logic module 15 of output (OUT) pulse 116 delivered through output line 106 in response to IN pulse 112 is measured by speed comparison logic module 15 relative to the arrival of EVALUATE signal 117 through evaluate line 107. As shown in FIG. 1B, when OUT pulse 116 arrives at the same time as EVALUATE signal 117, output logic signals FAST 119 and SLOW 118 at respective output logic lines fast 109 and slow 108 remain low. When OUT pulse 116 arrives after EVALUATE signal 117, output logic signal SLOW 118 is asserted, whereas when OUT pulse 116 arrives before EVALUATE signal 117, output logic signal FAST 119 is asserted.

FIG. 1C is a timing diagram depicting signals occurring under aliasing conditions in system 10. Aliasing occurs when delay line supply voltage VDD on voltage supply bus 110 is sufficiently low, i.e., delay line 13 is sufficiently slow, that two (or more) EVALUATE signal 127 periods elapse before delay line OUT pulse 126 arrives at speed comparison logic module 15. This causes an incorrect speed comparison, as illustrated in FIG. 1C, in which the first rising edge of IN pulse 122 initiates delay line evaluation, i.e., a test pulse begins propagating through delay line 13. At the first rising edge of EVALUATE signal 127, OUT pulse 126 has not yet reached speed comparison logic module 15, which causes SLOW output logic signal 128 to be asserted. This is the correct result. However, OUT pulse 126 finally arrives at speed comparison logic module 15 just prior to the second rising edge of EVALUATE signal 127, which causes FAST output logic signal 129 to be asserted. This result is incorrect, since the measurement was performed relative to the previous comparison's input IN pulse 122. The correct result should have been for SLOW output logic signal 128 to be asserted again.

### SUMMARY

In accordance with an embodiment disclosed herein, a circuit is provided. The circuit comprises a first delay line having a first input terminal operable to receive a first input signal, a first reset terminal operable to receive a first reset signal, and a first output terminal operable to provide a first output signal in response to the first input signal. The circuit further comprises a second delay line having a second input terminal operable to receive a second input signal, a second reset terminal operable to receive a second reset signal, and a second output terminal operable to provide a second output signal in response to the second input signal. The circuit further comprises a speed comparison logic module interconnected with the first output terminal, with the second output terminal, and with an evaluate terminal operable to receive an evaluate signal. The speed comparison logic module has at least one logic output terminal operable to assert a logic output signal in response to a comparison of the evaluate signal with one of the first output signal and the second output signal.

In accordance with another embodiment disclosed herein, a method for evaluating the speed of a circuit is provided. The method comprises concurrently launching a first input signal into a first delay line and applying a reset signal to a second delay line, such that all signals propagating through the second delay line are eliminated. The method further comprises initiating an evaluate signal, receiving a first output signal from the first delay line in response to the first input signal, receiving the evaluate signal, and asserting an output logic signal dependent on the time of receiving the first output signal relative to the time of receiving the evaluate signal. The method further comprises alternating the phases of the first delay line and the second delay line, concurrently launching a second input signal into the second delay line and applying a reset signal to the first delay line, such that all signals propagating through the first delay line are eliminated. The method further comprises initiating an evaluate signal, receiving a second output signal from the second delay line in response to the second input signal, receiving the evaluate signal, and asserting an output logic signal dependent on the time of receiving the second output signal relative to the time of receiving the evaluate signal.

In accordance with yet another embodiment disclosed herein, a system for evaluating the speed of a circuit is provided. The system comprises means for concurrently launching a first input signal into a first delay line and means for applying a reset signal to a second delay line, such that all signals propagating through the second delay line are eliminated. The system further comprises means for initiating an evaluate signal, means for receiving a first output signal from the first delay line in response to the first input signal, means for receiving the evaluate signal, means for asserting an output logic signal dependent on the time of receiving the first output signal relative to the time of receiving the evaluate signal, and means for alternating the phases of the first delay line and the second delay line, such that the functions of the first delay line and the second delay line are interchanged.

In accordance with yet another embodiment disclosed herein, a method for evaluating the speed of a circuit is provided. The method comprises determining during a first operational phase of a first operational cycle the propagation speed of a first signal in a first signal propagation path, and concurrently preventing all signals from propagating in a second signal propagation path substantially parallel with the first signal propagation path. The method further comprises determining during a second operational phase alternating with the first operational phase the propagation speed of a second signal in the second signal propagation path, and concurrently preventing all signals from propagating in the first signal propagation path.

### BRIEF DESCRIPTION OF THE DRAWINGS

FIG. 1A represents a system containing a traditional simple delay line, including a chain of inverters;

FIG. 1B is a timing diagram depicting signals occurring in traditional operation of the delay line shown in FIG. 1A;

FIG. 1C is a timing diagram depicting signals occurring under aliasing conditions in the system shown in FIG. 1A;

FIG. 2A depicts a system employing two alternating delay lines to carry out speed evaluations, in accordance with embodiments of the invention;

FIG. 2B is a timing diagram depicting signals occurring during the operation of the system shown in FIG. 2A;

FIG. 3 is a flow diagram depicting the operational cycle of the system shown in FIG. 2A;

FIG. 4A is a schematic diagram of a specialized delay line inverter, in accordance with embodiments of the invention;

FIG. 4B is a schematic diagram showing how the delay line inverter of FIG. 4A is used in a delay line, in accordance with embodiments of the invention;

FIG. 5 is a flow diagram illustrating a method, in accordance with an embodiment, for evaluating the speed of a circuit; and

FIG. 6 is a flow diagram illustrating another method, in accordance with another embodiment, for evaluating the speed of a circuit.

### DETAILED DESCRIPTION

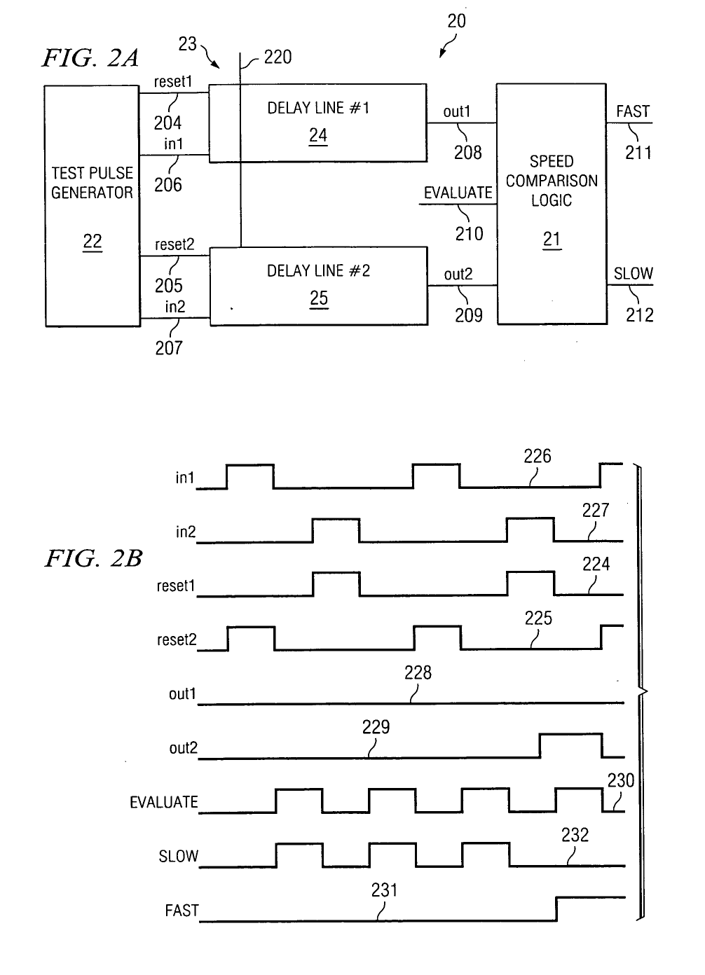

FIG. 2A depicts system 20 employing two alternating delay lines 24, 25 to carry out speed evaluations, in accordance with embodiments of the invention. Test pulse generator 22 is connected to first delay line 24 through first signal input line 206 and through first reset line 204. Likewise pulse generator 22 is connected to second delay line 25 through second signal input line 207 and through second reset line 205. Typically delay lines 24, 25 share a common supply voltage bus VDD 220, which also supplies voltage to other devices sharing the same microchip with system 20. First signal output line 208 from first delay line 24 and second signal output line 209 from second delay line 25 are connected to input terminals of speed comparison logic module 21. Evaluate line 210 is connected to a third input terminal of speed comparison logic module 21. Fast and slow output logic lines 211 and 212 respectively are provided from speed comparison logic module 21.

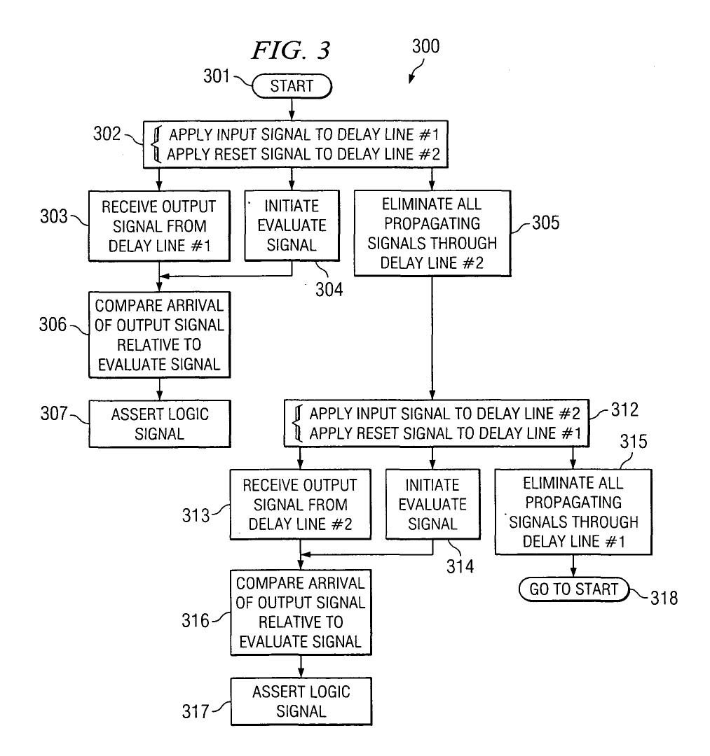

FIG. 2B is a timing diagram depicting signals occurring during the operation of system 20. FIG. 3 is a flow diagram depicting operational cycle 300 of system 20. Immediately after operational cycle START 301, IN signal 226 is launched in operation 302 from test pulse generator 22 into input terminal 206 of delay line 24 (Delay Line #1). Concurrently, RESET signal 225 is applied to reset terminal 205 of alternate delay line 25 (Delay Line #2). In operation 304, as determined by timing circuitry of system 20, EVALUATE signal 230 is initiated into evaluate terminal 210 of speed comparison logic module 21. While delay line 24 is evaluating (a signal is propagating through its circuitry), delay line 25 is resetting. During the reset phase depicted in operation 305, delay line 25 is completely cleared, so that any signals from the previous evaluate cycle are eliminated. In the meantime, in operation 303, OUT signal 228 from delay line 24 in response to IN signal 226 is received at speed comparison logic module 21 through signal output line 208, and in operation 306, its arrival time is compared with that of EVALUATE signal 230. In operation 307, speed comparison logic module 21 then asserts SLOW output logic signal 232 or FAST output logic signal 231, dependent on the arrival time of OUT signal 228 relative to the arrival time of EVALUATE signal 230.

The system is controlled entirely by timing circuitry. So, delay line 24 will not wait for delay line 25 to evaluate before it begins its evaluation and vice-versa. All IN pulses, EVALUATE pulses, and RESET pulses are timing-based, and in the specific implementation of FIGS. 2A and 2B are based on the system clock frequency to provide an accurate measurement of the digital system timing deadlines. Delay line 24 enters the reset phase, and concurrently IN2 signal 227 is launched through delay line 25, as depicted in operation 312. In operation 314, EVALUATE signal 230 is launched into evaluate terminal 210 of speed comparison logic module 21. While delay line 25 is evaluating, delay line 24 is resetting. During the reset phase depicted in operation 315, delay line 24 is completely cleared, so that any signals from the previous evaluate cycle are eliminated. In the meantime, in operation 313, OUT2 signal 229 from delay line 25 in response to IN2 signal 227 is received at speed comparison logic module 21 through signal output line 209, and in operation 316, its arrival time is compared with that of EVALUATE signal 230. In operation 317, speed comparison logic module 21 then asserts SLOW output logic signal 232 or FAST output logic signal 231, dependent on the arrival time of OUT signal 229 relative to the arrival time of EVALUATE signal 230. System 20 then recycles to operational cycle START 301.

Particularly, in the last phase of the timing cycles shown in FIG. 2B, EVALUATE 230 is high, RESET2 225 is low, OUT1 228 is low, OUT2 229 is high (leading edge preceding leading edge of EVALUATE 230), SLOW 232 is low, and FAST 231 is asserted. RESET1 224 has already cleared out Delay Line #1 24, prior to the current assertion of EVALUATE 230. Speed comparison logic 21 is evaluating OUT2 229 from Delay Line #2 25 as long as EVALUATE 230 remains high in this phase. RESET2 225 remains low while EVALUATE 230 remains high, and is asserted (goes high) only at the same time that EVALUATE 230 goes low, as controlled by timing circuitry. This timing relationship assures that speed comparison logic 21 has completed evaluating OUT2 229 for a respective operating cycle, before the next assertion of RESET2 forces OUT2 229 to clear. In the alternating phase of the operating cycle, a similar timing relationship exists between RESET1 224 and EVALUATE 230.

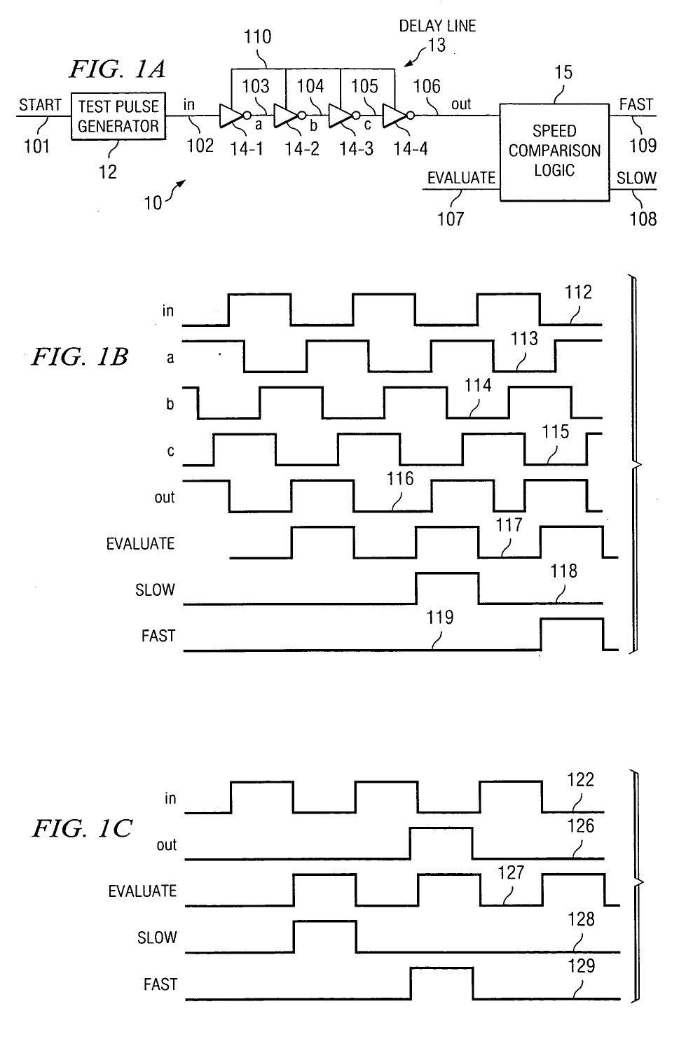

By alternating delay lines 24, 25 in the manner depicted in FIG. 3 between reset and evaluate phases, the same frequency of comparisons is performed as was performed using traditional system 10 depicted in FIG. 1A, but cycle-to-cycle aliasing is prevented. For example, in the aliasing scenario depicted in FIG. 2B, delay line 24 is sufficiently slow that IN pulses 226 require more than two cycles of EVALUATE signal 230 to arrive at the delay line outputs as OUT pulses 228. Then OUT pulse 228 does not arrive in time for comparison, and SLOW output logic signal 232 is asserted correctly, because delay line 24 is reset alternately by applying RESET signal 224 between evaluations. By contrast, although output pulse 229 from first IN pulse 227 of delay line 25 arrives too late relative to EVALUATE signal 230 for comparison, output pulse 229 from second IN pulse 227 of delay line 25 arrives in advance of fourth cycle of EVALUATE pulse 230, and correctly asserts FAST output logic signal 231. If output pulse 229 had been generated in response to an earlier cycle IN signal 227, it would have been cleared out by second RESET signal cycle 225 before evaluating.

The manner in which reset of a delay line is performed depends on the specific delay line implementation. In one such implementation, a pull-down nfet that turns on during reset and forces these nodes to zero is added to alternating stages of the delay line.

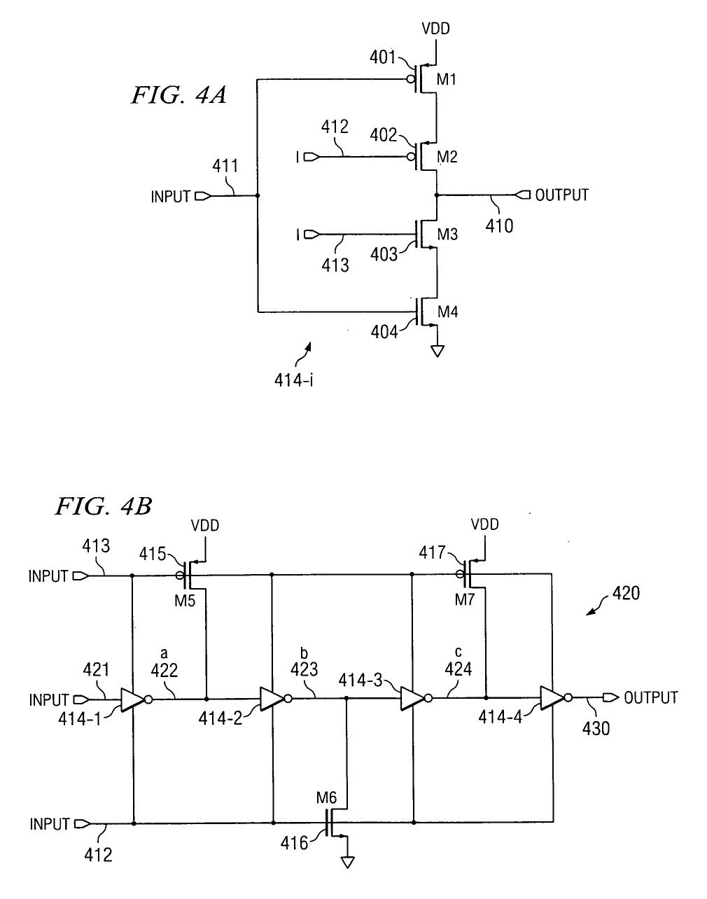

FIG. 4A is a schematic diagram of a specialized delay line inverter 414-i. It has three inputs: IN 411, RESET 412, and RESET_BAR 413. It has a single output, OUT 410. The signal RESET 412 is asserted (binary 1) during the delay line reset phase, and RESET_BAR 413 is always the logical inverse of RESET 412. Functionally, when delay line inverter 414-i is not resetting (i.e. RESET 412 is binary 0 and RESET_BAR 413 is binary 1), it behaves like a traditional inverter controlled by traditional MOSFETs M1 401 and M4 404, in that OUT 410 is the inverse of IN 411. During the delay line evaluate phase, MOSFETs M2 402 and M3 403, are turned on, such that normal inverter evaluation can occur. During the reset phase, RESET 412 is binary 1 and RESET_BAR 413 is binary 0. This turns off MOSFETs M2 402 and M3 403 such that inverter 414-i cannot drive a value onto OUT 410. At this point, an external transistor 415-417 (shown in FIG. 4B) is able to drive a value onto OUT 410 without a “drive fight.”

FIG. 4B is a schematic diagram showing how delay line inverter 414-i is used in delay line 420. Each of inverters 414-1, . . . , 414-4 in FIG. 4B is specialized inverter 414-i shown in FIG. 4A. On a delay line evaluation, a positive test pulse (a binary 1 signal) is driven into input 421 of delay line 420. By definition, a cleared out delay line is one in which binary 0 is asserted on input 421, and consequently binary 0 evaluates at output 430. Specifically, a fully reset delay line has the following binary values on its nodes: delay_line_in 421=0, node 422=1, node 423=0, node 424=1, delay_line_out 430=0. MOSFETs M5, M6 and M7 (415-417) actually force nodes 422-424 to the correct binary values, so delay line reset requires only a delay of one delay line element. This is a fast reset, enabled by specialized inverter 414-i and reset MOSFETs 415-417 in delay line circuit 420. This fast reset is an important property of the alternating delay lines implementation.

An alternative solution that could be used to remove aliasing from systems incorporating delay lines is to use dynamic logic in the delay line, such that the delay line is cleared out during the precharge phase just by nature of the delay line implementation. S. Dhar et al., “Low-Power Digital Filtering Using Multiple Voltage Distribution and Adaptive Voltage Scaling,” paper submitted to International Symposium on Low Power Electronic Design, 2000, hereby incorporated herein by reference, describes the use of dynamic-circuit delay lines. By its very nature, dynamic logic is anti-aliasing due to its inherent precharge phase. But with dynamic logic, full cycle evaluate cannot be achieved, because the precharge phase encroaches into the timing budget. The embodiments disclosed herein allow ANY type of logic to achieve the delay vs. VDD response needed to match chip critical paths. They also allow a delay line evaluation period of any duration up to a full clock cycle. A problem with the scheme documented by Dhar et al. is that the precharge time encroaches into a portion of the system clock period. Thus, it is impossible to create a delay line that completely mimics a full cycle of the system clock, without using two delay lines, as the present embodiments disclose. Another problem with using a purely dynamic logic implementation of the delay line is that it does not accurately model the speed of the digital system circuits, unless the system itself is made entirely of dynamic logic. Static and dynamic logic are terms defined in the art. “Design of High-Performance Microprocessor Circuits,” edited by Anantha Chandrakasan, et al., IEEE Press 2001, defines static logic on page 120, section 7.2.1 and defines dynamic logic on page 128, section 7.3.1, which pages are hereby incorporated by reference herein. It is noted that dynamic logic is also interchangeably called “domino logic.” Because dynamic and static logic respond differently to changes in supply voltage, a purely dynamic logic delay line cannot accurately respond to the speed changes that occur in static logic.

A second solution that may be employed to remove aliasing from a delay-line based system is to decrease the frequency of evaluations, such that the delay line is guaranteed to completely evaluate for all desired operating points of the digital system. T. Kuroda, et al., “Variable Supply-Voltage Scheme for Low-Power High Speed CMOS Digital Design,” IEEE Journal of Solid-State Circuits, vol. 33, pp. 454-462, hereby incorporated by reference herein, describes a system that waits between delay line evaluations to eliminate aliasing. A major disadvantage of this implementation is that the frequency of evaluations must decrease, which in turn decreases the overall dynamic response of the power management scheme.

In a power management system as previously described, some means of measuring the speed of the chip's critical paths is required, to tell the system how to adjust the system clock so that system integrity is maintained. The goal is to decrease the operating frequency just enough that critical paths meet their timing deadlines, but no more, because a further decrease in frequency causes system performance to drop. A delay line can be used in such a power management system to estimate the speed of the chip critical paths and tell the system's clock generation circuitry how to adjust the clock frequency. For example, in FIGS. 2A and 2B, the FAST output of the speed comparison logic would indicate that the delay lines and, therefore, the system critical paths are fast. This implies that the supply voltage is high enough that the clock frequency can be increased to gain performance. Similarly, when the SLOW output is asserted, this means that the delay lines and corresponding system critical paths are too slow, possibly due to the power management system decreasing VDD to stay within its power budget, or due to a power grid droop. In response to SLOW asserting, the system clock generation circuitry decreases the system clock frequency, so that the chip critical paths meet their timing deadlines.

One major challenge associated with this type of power management system is designing a delay line that accurately measures the speed of the actual system critical path(s). Since the actual chip critical path is NOT known at design time and could even vary from chip to chip, the delay lines must be tuned in actual silicon to match what each chip's critical path turns out to be. An advantageous way to do this is to design the delay line circuit, such that it is composed of circuits that respond to supply voltage changes in a manner that is similar to the circuits in the digital system, to allow flexibility in this silicon tuning. For example, in custom VLSI design, there are a few circuit families that are in common use. These are full complementary CMOS (or static logic), dynamic logic, and RC-dominated paths common in signals that must be buffered and routed a long distance on the chip. Therefore, designing a delay line that responds to supply voltage changes in a manner that is similar to these logic families is important to get an accurate estimate of how fast the digital system can run. Furthermore, each of these circuit types exhibits a unique delay response to supply voltage changes. For example, designing a delay line that uses dynamic logic as an estimate of how fast a static logic path is operating in the digital system is not very accurate. The cost of doing so is inferior system performance.

A potential pitfall of a delay line based speed estimation circuit is cycle-to-cycle aliasing. Because the power management system and clock system are dynamically adjusting supply voltage and frequency, it is possible for the supply voltage to be adjusted low enough that the delay lines slow down so much that a test pulse gets “trapped” in the delay line. The “trapped” pulse does not appear at the input to the speed comparison logic until the next assertion of EVALUATE. In this situation, it is likely that the speed comparison logic will interpret this late pulse as an indication that the delay lines are running fast, and consequently will assert FAST as shown in FIG. 1B. In turn, this will cause the clock generators to increase the clock frequency, and will cause the chip critical paths to miss their deadlines. Due to this error, the system cannot recover and will begin generating erroneous results. Clearing out the alternating delay lines before each one evaluates, as described in accordance with the embodiments herein, completely removes the potential for aliasing in the system.

The present dual delay line scheme allows for a delay line that is made up of any type or combination of types of circuitry. For example, the delay line can be implemented using either static and dynamic logic stages, provided that it is implemented such that it can be cleared during the reset phase. This is highly desirable, because actual digital system critical paths are usually made up of some combination of these logic types, and the delay line can be designed to model actual system paths more realistically. Embodiments disclosed herein remove cycle-to-cycle aliasing in delay-line based digital circuit speed-measuring circuits, while allowing the same evaluation frequency that can be employed with a single delay line-based system.

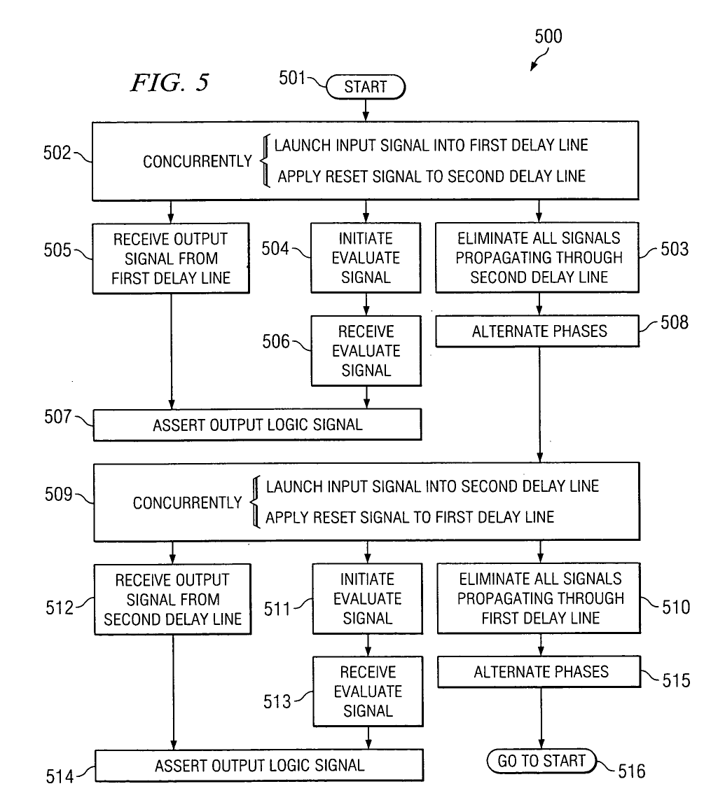

FIG. 5 is a flow diagram illustrating method 500, in accordance with an embodiment, for evaluating the speed of a circuit. The method comprises, as depicted in operation 502, launching first input signal 226 into first delay line 24 and concurrently applying reset signal 225 to second delay line 25, such that all signals 227, 229 propagating through second delay line 25 are eliminated, as further depicted in operation 503. The method further comprises initiating evaluate signal 230, as depicted in operation 504; receiving first output signal 228 from first delay line 24 in response to first input signal 226, as depicted in operation 505; and receiving evaluate signal 230, as depicted in operation 506. The method further comprises asserting output logic signal 231, 232, dependent on the time of receiving 505 first output signal 228 relative to the time of receiving 506 evaluate signal 230, as depicted in operation 507. The method further comprises alternating the phases of first delay line 24 and second delay line 25, as depicted in operation 508, and concurrently launching second input signal 227 into second delay line 25 and applying reset signal 224 to first delay line 24, as depicted in operation 509, such that all signals 226, 228 propagating through first delay line 24 are eliminated, as depicted in operation 510. The method further comprises initiating evaluate signal 230, as depicted in operation 511; receiving second output signal 229 from second delay line 25 in response to second input signal 227, as depicted in operation 512; and receiving evaluate signal 230, as depicted in operation 513. The method further comprises asserting output logic signal 231, 232, dependent on the time of said receiving 512 second output signal 229 relative to the time of said receiving 513 evaluate signal 230, as depicted in operation 514.

Dependent on timing signals, the method comprises another alternating of phases of first delay line 24 and second delay line 25, as depicted in operation 515, followed by returning operational flow in operation 516 to start in operation 501.

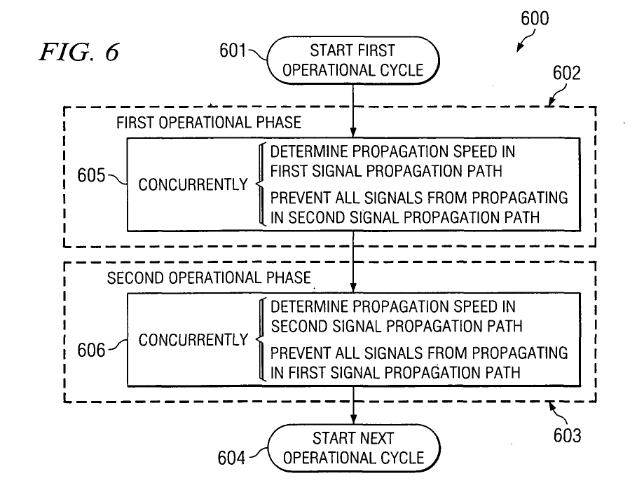

FIG. 6 is a flow diagram illustrating method 600, in accordance with another embodiment, for evaluating the speed of a circuit. The method comprises determining during a first operational phase 602 of a first operational cycle 601 the propagation speed of a first signal 226, 228 in first signal propagation path 24, and concurrently preventing 225 all signals 227, 229 from propagating in second signal propagation path 25 substantially parallel with first signal propagation path 24, as depicted in operation 605. The method further comprises determining during second operational phase 603 alternating with first operational phase 602 the propagation speed of a second signal 227, 229 in second signal propagation path 25, and concurrently preventing 224 all signals 226, 228 from propagating in first signal propagation path 24, as depicted in operation 606.

In operation 604, operational flow is returned to operation 601 to start a next operational cycle.

1. A circuit comprising:
a first delay line having a first input terminal operable to receive a first input signal, a first reset terminal operable to receive a first reset signal, and a first output terminal operable to provide a first output signal in response to said first input signal;
a second delay line having a second input terminal operable to receive a second input signal, a second reset terminal operable to receive a second reset signal, and a second output terminal operable to provide a second output signal in response to said second input signal; and
a speed comparison logic module interconnected with said first output terminal, with said second output terminal, and with an evaluate terminal operable to receive an evaluate signal, said speed comparison logic module having at least one logic output terminal operable to assert a logic output signal in response to a comparison of said evaluate signal with one of said first output signal and said second output signal.

2. The circuit of claim 1 further comprising a voltage supply bus interconnected with voltage supply terminals of said first delay line and of said second delay line.

3. The circuit of claim 1 further comprising a test pulse generator operable to provide said first input signal and said second input signal, said test pulse generator interconnected with said first input terminal and with said second input terminal.

4. The circuit of claim 3 wherein said test pulse generator is interconnected with said first reset terminal and with said second reset terminal.

5. The circuit of claim 1 wherein said first delay line comprises a chain of inverters.

6. A method for evaluating the speed of a circuit, said method comprising:
concurrently launching a first input signal into a first delay line and applying a reset signal to a second delay line, such that all signals propagating through said second delay line are eliminated;
initiating an evaluate signal;
receiving a first output signal from said first delay line in response to said first input signal;
receiving said evaluate signal;
asserting an output logic signal dependent on the time of said receiving said first output signal relative to the time of said receiving said evaluate signal;
alternating the phases of said first delay line and said second delay line, concurrently launching a second input signal into said second delay line and applying a reset signal to said first delay line, such that all signals propagating through said first delay line are eliminated;
initiating an evaluate signal;
receiving a second output signal from said second delay line in response to said second input signal;
receiving said evaluate signal; and
asserting an output logic signal dependent on the time of said receiving said second output signal relative to the time of said receiving said evaluate signal.

7. The method of claim 6 wherein said output logic signal is selected from the group consisting of high slow, low slow, high fast, and low fast.

8. The method of claim 6 further comprising fabricating said circuit, said first delay line, and said second delay line on a common semiconductor wafer substrate.

9. The method of claim 6 wherein said reset signal is applied by turning on a pull-down nfet, such that a node of one of said first delay line and said second delay line is forced to zero.

10. The method of claim 6 wherein said first and said second input signals, said first and said second reset signals, and said evaluate signal are all timed by timing circuitry.

11. A system for evaluating the speed of a circuit, said system comprising:
means for concurrently launching an input signal into a first delay line and means for applying a reset signal to a second delay line, such that all signals propagating through said second delay line are eliminated;
means for initiating an evaluate signal;
means for receiving an output signal from said first delay line in response to said input signal;
means for receiving said evaluate signal;
means for asserting an output logic signal dependent on the time of said receiving said output signal relative to the time of said receiving said evaluate signal;
means for alternating the phases of said first delay line and said second delay line, such that the functions of said first delay line and said second delay line are interchanged.

12. The system of claim 11 wherein said output logic signal is selected from the group consisting of high slow, low slow, high fast, and low fast.

13. The system of claim 11 further comprising means for applying said reset signal by turning on a pull-down nfet, such that a node of one of said first delay line and said second delay line is forced to zero.

14. The system of claim 11 wherein said means for launching said input signal, means for applying said reset signal, and means for initiating an evaluate signal comprise timing signals.

15. A method for evaluating the speed of a circuit, said method comprising:
determining during a first operational phase of a first operational cycle the propagation speed of a first signal in a first signal propagation path, and concurrently preventing all signals from propagating in a second signal propagation path substantially parallel with said first signal propagation path; and
determining during a second operational phase alternating with said first operational phase the propagation speed of a second signal in said second signal propagation path, and concurrently preventing all signals from propagating in said first signal propagation path.

16. The method of claim 15 wherein said propagation speed is determined by comparing the propagation time of an evaluate signal relative to the propagation time of one of said respective first signal and said second signal.

17. The method of claim 15 further comprising asserting an output logic signal dependent on said propagation time of one of said respective first signal and said second signal relative to said propagation time of said evaluate signal.

18. The method of claim 17 wherein said output logic signal is selected from the group consisting of high slow, low slow, high fast, and low fast.

19. The method of claim 15 wherein said preventing all signals from propagating comprises applying a reset signal.

20. The method of claim 19 wherein said first signal propagation path and said second signal propagation path comprise respectively a first delay line and a second delay line.

21. The method of claim 20 wherein said reset signal is applied using a pull-down nfet, such that a node of one of said first delay line and said second delay line is forced to zero.

22. The method of claim 20 further comprising fabricating said circuit, said first delay line, and said second delay line on a common semiconductor wafer substrate.

23. The method of claim 16 wherein said first and said second input signals, said preventing, and said evaluate signal are all timed by timing circuitry.
